(19) United States
(12) Patent Application Publication
(10) Pub. No.: US 2026/0148793 A1
(43) Pub. Date: May 28, 2026

(54) RELIABILITY BOOSTING OF A STORAGE DEVICE FOR AN IN-MEMORY GARBAGE COLLECTION OPERATION

(71) Applicant: SK hynix Inc., Gyeonggi-do (KR)

(72) Inventors: Fan Zhang, Fremont, CA (US); Pengfei Huang, San Jose, CA (US); Meysam Asadi, Livermore, CA (US)

(21) Appl. No.: 18/962,388

(22) Filed: Nov. 27, 2024

(51) Int. Cl. G11C 29/42; G11C 29/12

(52) U.S. Cl. CPC G11C 29/42; G11C 29/12005; G11C 29/12015

(57) ABSTRACT

Techniques to boost reliability of a storage device may include performing an in-memory garbage collection operation to transfer data from a source memory block to a target memory block inside a memory device without using a memory controller. The in-memory garbage collection operation may cause soft errors in the source memory block to be converted into hard errors in the target memory block. In response to a test read of the target memory block, it may be determined that the target memory block has a failed bit count (FBC) greater than a FBC threshold by taking into account a degradation of a soft error decoder correction capability caused by the hard errors from the in-memory garbage collection operation. An external garbage collection operation may be performed on the target memory block to reclaim the target memory block.

### BACKGROUND

Garbage collection is a memory management function in storage devices that can be periodically performed by a memory controller in the storage device to optimize the use of the memory. Garbage collection generally includes relocating valid data from partially filled memory blocks in the memory to free up those memory blocks to store new data. In most cases, the valid data is moved from a partially filled memory block to a new memory block, and the old memory block is deallocated to be ready for writing the new valid data. In some cases, internal garbage collection operation may be performed by the memory device without using the memory controller, which may reduce write amplification and improve the performance of the storage device for the garbage collection process.

### BRIEF SUMMARY

Techniques for boosting reliability of a storage device upon introduction of hard errors resulting from the in-memory garbage collection operation are described. The storage device may perform an in-memory garbage collection operation to transfer data from a source memory block to a target memory block inside a memory device without using a memory controller. The in-memory garbage collection may be performed by the memory device when a partial checksum (PCS) computed by the memory device is below a threshold. The in-memory garbage collection operation may cause soft errors in the source memory block to be converted into hard errors in the target memory block. The storage device may determine that the target memory block has a failed bit count (FBC) greater than a FBC threshold in response to a test read of the target memory block by taking into account a degradation of a soft error decoder correction capability caused by the hard errors from the in-memory garbage collection operation. The storage device may perform an external garbage collection operation on the target memory block to reclaim the target memory block.

In one implementation, the FBC threshold may be a hard error decoder correction capability threshold. The degradation of the soft error decoder correction capability may be taken into account by adjusting an interval for performing the test read. The test read may be part of a media scan of the memory device performed over a scan time period, and adjusting the interval may include adjusting the scan time period. The adjusted scan time period may be equal to or shorter than an amount of time for a data retention FBC to increase from the hard error decoder correction capability threshold to a degraded soft error decoder correction capability threshold resulting from presence of the hard errors.

The test read may be part of a single page read (SPRD) test that is performed after a threshold number of reads on the target memory block, and adjusting the interval may include adjusting the threshold number of reads to trigger the SPRD test. The threshold number of reads may be equal to or less than a number of reads for a read disturb FBC to increase from the hard error decoder correction capability threshold to a degraded soft decoder correction capability threshold resulting from presence of the hard errors.

The interval for performing the test read may be further adjusted based on a life cycle stage of the memory device.

In one implementation, the degradation of the soft error decoder correction capability may be taken into account by adjusting the FBC threshold for determining to reclaim the target memory block. The adjusted FBC threshold may be equal to or less than a threshold obtained by reducing the hard error decoder correction capability threshold by an amount of the degradation of the soft error decoder correction capability resulting from presence of the hard errors.

In some implementations, a storage device may comprise a memory controller having a soft error decoder and a hard error decoder, and a memory device having an internal garbage collection logic operable to perform an in-memory garbage collection operation to transfer data from a source memory block to a target memory block inside the memory device. The memory device may be operable to perform the in-memory garbage collection when a partial checksum (PCS) computed by the memory device is below a threshold. The in-memory garbage collection operation may cause soft errors in the source memory block to be converted into hard errors in the target memory block. The memory controller may be further operable to determine that the target memory block has a failed bit count (FBC) greater than a FBC threshold in response to a test read of the target memory block by taking into account a degradation of a soft error decoder correction capability of the soft error decoder caused by the hard errors from the in-memory garbage collection operation, and perform an external garbage collection operation on the target memory block to reclaim the target memory block.

The memory controller is further operable to take the degradation of the soft error decoder correction capability into account by adjusting an interval for performing the test read. The memory controller is further operable to adjust the interval for performing the test read based on a life cycle stage of the memory device.

The memory controller is further operable to take the degradation of the soft error decoder correction capability into account by adjusting the FBC threshold for determining to reclaim the target memory block. The adjusted FBC threshold may be equal to or less than a threshold obtained by reducing the hard error decoder correction capability threshold by an amount of the degradation of the soft error decoder correction capability resulting from presence of the hard errors.

### BRIEF DESCRIPTION OF THE DRAWINGS

The detailed description below makes reference to a few example embodiments that are illustrated in the accompanying drawings. However, it should be understood that the description is equally relevant to various other variations of the embodiments described herein. Such embodiments may utilize objects and/or components other than those illustrated in the drawings. It should also be understood that like reference numerals used in the various figures indicate similar or identical objects.

FIG. 1 illustrates a storage device comprising a memory controller coupled to a memory device operable to perform an internal garbage collection operation.

FIG. 2 illustrates an example graph showing distribution of a failed bit count (FBC) against an inverse cumulative distribution function (ICDF) for an external garbage collection process.

FIG. 3 illustrates an example graph showing distribution of a FBC against an ICDF for an internal and an external garbage collection process.

FIG. 4 illustrates an example graph showing distribution of a FBC against an ICDF with a reduction in the scan time period due to degradation of the soft error decoder correction capability resulting from an internal garbage collection operation, in some embodiments of the disclosure.

FIG. 5 illustrates an example graph showing distribution of a FBC against an ICDF with a reduction in a FBC threshold due to degradation of the soft error decoder correction capability resulting from an internal garbage collection operation, in some embodiments of the disclosure.

FIG. 6 illustrates a block diagram of an example error correction system that can support boosting reliability of a storage device, in accordance with some embodiments of the disclosure.

FIG. 7 illustrates a simplified flow chart of an example process to boost reliability of a storage device in accordance with the disclosure.

FIG. 8 shows a simplified block diagram illustrating a solid-state storage device, which can be an example of an electronic device utilizing the reliability boosting techniques described herein.

FIG. 9 illustrates a computer system usable for implementing one or more embodiments of the present disclosure.

### DETAILED DESCRIPTION

Data storage devices, such as solid-state storage devices, may include multiple memory dies, and each memory die may be organized into a plurality of memory blocks. Each memory block may include multiple memory pages. Generally, when a data storage device is written with data (e.g., files or other chunks of data) into memory pages, the data may not always align with the memory block based on the size of the data being written. Thus, in most cases, a large number of memory blocks may be partially filled with valid memory pages, and each of those partially filled memory blocks may include invalid (unused or fractured) empty space that may not be usable, which may not be the most efficient use of the memory. Garbage collection operation is a memory management function that may be performed by a memory controller of the storage device to consolidate the data from the valid memory pages of a partially filled memory block into a new memory block. Thus, combining valid memory pages from partially filled memory blocks into one or more new memory blocks can eliminate fractured empty spaces, and free up those partially filled memory blocks to store new data in an efficient manner.

Generally, the firmware executing on the memory controller may trigger the garbage collection operation and instruct the memory controller to read the valid data from the old memory block in the memory device. The data is transferred from the memory device to the memory controller. The memory controller may then perform error correction decoding on the data read from the old memory block, and write the error-free data to the new memory block in the memory device. The memory controller may de-allocate or erase the old memory block to free-up the memory space for the new write operations. The garbage collection operation performed by the memory controller (also called external garbage collection, herein) can help with the memory management of the memory device, but may cause some performance drawbacks. For example, the external garbage collection operation may cause write amplification since each write operation to the memory device may get translated to multiple write operations. Furthermore, external garbage collection operations may collide with the normal write operations to the memory device, which may impact the throughput and the quality-of-service (QoS) of the storage device.

To alleviate the impact of garbage collection, an in-memory or internal garbage collection operation may be performed to reduce the write amplification as well as frequent data movement between the memory device and the memory controller. For example, the memory device may perform the internal garbage collection by reading data from the valid memory pages in a source memory block, determining whether a checksum metric of the valid memory pages is below a threshold value, and writing the data to a target memory block if the checksum metric is below the threshold value. If the checksum metric of the valid memory pages is above the threshold value, the memory device may request the memory controller to perform the external garbage collection operation. The threshold value can be based on the number of parity bits in a low-density parity check (LDPC) codeword used by the storage device.

Generally, partial checksum (PCS) is a good indication of a failed bit count (FBC) of the memory pages. For example, a value of PCS increases with an increase in the FBC. Thus, a decision based on the PCS value can be made to perform an in-memory garbage collection or external garbage collection. When a PCS of a memory page is below the threshold value, an in-memory or internal garbage collection operation may be performed. Most of the memory pages under different memory conditions are generally with low to median FBC, and can be copied to the target memory block with the in-memory garbage collection capability. When the PCS is above the threshold value, the memory device may request the memory controller to perform the external garbage collection operation. In this scenario, the memory controller may correct the errors in the decoded data, and write the error-free data back to the target memory block.

The storage device may perform a media scan process periodically to monitor health of the memory device. The media scan process may include performing test reads of each memory block of the entire memory device over a scan time period to check for any errors. In some implementations, a FBC of the decoded data from the test read of each memory block may be compared with a hard error decoder correction capability threshold of a hard decoder, which is lower than a soft error decoder correction capability threshold of a soft decoder. The scan time period to scan the entire storage device is generally set to an amount of degradation time for the FBC to increase from the hard error decoder correction capability threshold to the soft error decoder correction capability threshold. If the FBC of a given memory block is lower than the hard error decoder correction capability threshold, it may indicate that no garbage correction is needed since the worst case FBC will not exceed the soft error decoder correction capability threshold within the scan time period. However, if the FBC is higher than the hard error decoder correction capability threshold, external garbage collection may be performed to correct the errors, and copy the corrected data back to the memory block because the FBC may degrade beyond the soft decoder capability by the time the media scan test completes.

However, when the in-memory garbage collection is performed to copy data from the source memory block to the target memory block, soft errors may become hard errors in the target memory block. A hard error may be defined for a cell having a voltage on the wrong side of an optimal sensing bias and outside of a soft range. For example, for a triple-level cell (TLC) NAND memory, the soft range may generally be defined as a range in the order of plus or minus a hundred mV or more around the optimal sensing bias. Hard errors may not affect the correction capability of hard decoders, such as, bit-flip (BF) decoders and min-sum hard (MSH) decoders. However, depending on the percentage of hard errors, the soft error decoder correction capability of the soft decoder (e.g., min-sum soft (MSS) decoder) may be degraded. In an extreme case, when all errors are hard errors, the soft error decoder correction capability may become same as the hard error decoder correction capability. Thus, reliability of the storage device may be reduced when the hard errors are introduced as a result of the in-memory garbage collection operation.

Techniques to boost reliability of a storage device upon introduction of hard errors resulting from the in-memory garbage collection operation are described. A media scan process may be performed to test read each memory block of the entire storage device over a scan time period. When an FBC from the test read of the target memory block is greater than a FBC threshold due to introduction of the hard errors, a degradation of the soft error decoder correction capability caused by the hard errors from the in-memory garbage collection operation is taken into account, and an external garbage collection operation may be performed on the target memory block to reclaim the target memory block.

In one implementation, degradation of the soft error decoder correction capability may be taken into account by adjusting an interval for performing the test read or shortening the scan time period to be same as the degradation time for the FBC threshold to increase from a hard error decoder correction capability threshold to a degraded soft error decoder correction capability threshold. In another implementation, degradation of the soft error decoder correction capability may be taken into account by adjusting the FBC threshold for determining to reclaim the target memory block to be the same or less than a difference between the degraded soft error decoder correction capability threshold and the hard error decoder correction capability threshold.

In the description provided herein, for the purposes of explanation, specific details are set forth in order to provide a thorough understanding of certain inventive embodiments. However, it will be apparent that various embodiments may be practiced without these specific details. Hence, the figures and description are not intended to be restrictive. Certain words and phrases are used herein based on convenience and such words and phrases should be interpreted in various forms and equivalencies by persons of ordinary skill in the art. For example, the word “bit” as used herein represents a binary value (either a “1” or a “0”) that can be stored in a memory. Furthermore, it should be understood that each of words such as “implementation,” “scenario,” “approach,” “application,” “case” and “configuration” as used herein is an abbreviated version of the phrase “In an example (“implementation,” “scenario,” “approach,” “application,” “case,” “configuration” etc.) in accordance with disclosure.” It must also be understood that the word “example” as used herein is intended to be non-exclusionary and non-limiting in nature.

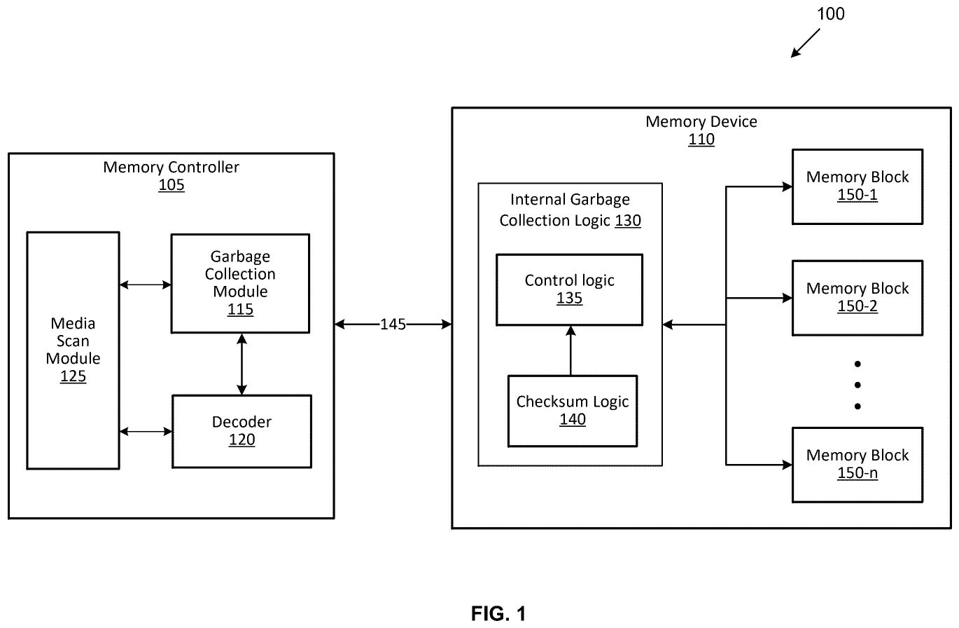

FIG. 1 illustrates a storage device 100 comprising a memory controller 105 coupled to a memory device 110 operable to perform an internal garbage collection operation.

The memory device 110 may include an N number of memory blocks comprising memory blocks 150-1, 150-2, and 150-n. The N number of memory blocks may be arranged in any suitable configuration based on the type of the flash memory. The memory device 110 may also include an internal garbage collection logic 130 comprising control logic 135, and checksum logic 140. Each of the N memory blocks may include a plurality of memory pages. In some examples, some of the memory blocks may only be partially filled. For example, a partially filled memory block may include a few valid memory pages, and remaining memory space may be unused or invalid.

The memory controller 105 may include a garbage collection module 115, a decoder 120, and a media scan module 125. The memory controller 105 may also include one or more processors (not shown) that can be configured to execute instructions stored in a computer readable medium. For example, the memory controller 105 may execute firmware that may be operable to manage read/write accesses to the memory device 110, and communicate with a host device, among other tasks. In some embodiments, the firmware may also be operable to determine that a garbage collection operation needs to be performed on the memory device 110 based on a certain trigger. For example, a trigger may be generated when a number of empty memory blocks available to write new data falls below a predefined value, or a number of partially filled blocks exceeds a certain threshold. However, any suitable condition can be used to trigger the garbage collection process without deviating from the scope of the disclosure. In some embodiments, the firmware may also be operable to configure the media scan module 125 with a frequency to perform the media scan process periodically to scan the entire memory device 110 over a scan time period.

The garbage collection module 115 may be operable to determine that a garbage collection operation is to be performed to move valid memory pages from a source memory block to a target memory block in the memory device 110 based on the trigger. For example, the source memory block may be the memory block 150-1, and the target memory block may be the memory block 150-2. The decoder 120 may be operable to decode the data read from the memory pages of the memory block 150-1, perform error correction on the decoded data, and write the corrected data to the memory block 150-2. Some example implementations of the decoder 120 may include a decoder hierarchy comprising a hard decoder having a hard error decoder correction capability to correct hard errors, and a soft decoder having a soft error decoder correction capability to correct soft errors.

The internal garbage collection logic 130 may be operable to perform the in-memory garbage collection when the FBC of a memory block is below a FBC threshold. In some implementations, a partial checksum (PCS) of a memory block can be used to estimate the FBC. The checksum logic 140 may be used to determine the PCS from a portion of the LDPC codeword. The control logic 135 may be further operable to compare the PCS computed by the checksum logic 140 to determine whether the PCS is below a threshold value. The threshold value may be determined based on the number of parity bits in the LDPC codeword used by the storage device. If the control logic 135 determines that the PCS is above the threshold value, the control logic 135 may request the memory controller 105 to perform the garbage collection operation. In some implementations, the control logic 135 may enable a bit/flag that generates an interrupt to the memory controller 105 to request the memory controller 105 to perform the garbage collection operation. In this scenario, the memory controller 105 may perform a read operation of the memory device 110 to read the valid memory pages from the source memory block, perform error correction on the data read from the valid memory pages, and write the corrected data to the target memory block.

If the control logic 135 determines that the PCS is below the threshold value, the control logic 135 may further attempt to perform the in-memory garbage collection operation to internally move valid memory pages from the source memory block to the target memory block. In some examples, the internal garbage collection logic 130 may include a lightweight ECC engine (not shown) to correct the errors before writing the valid memory pages to the target memory block. In some examples, if the error count is very low, the control logic 135 may write the valid memory pages having the low error count to the target memory block with the assumption that these errors may be corrected by the memory controller 105 in the future when performing a read operation of the target memory block.

The media scan module 125 may be operable to periodically perform a media scan of the memory device 110 over a scan time period (e.g., 15 days). For example, the media scan module 125 may perform a test read of each memory page of the memory device 110 at least once within the scan time period to ensure that the stale pages do not have any errors and can retain the data. The scan time period may be set to an amount of degradation time for the FBC to increase from a hard error decoder correction capability threshold to a soft error decoder correction capability threshold. The media scan module 125 may be further operable to compare the FBC from the test read of a memory block with a FBC threshold corresponding to the hard error decoder correction capability threshold. If the FBC is below the FBC threshold, it may indicate that the worst case FBC may not exceed the soft error decoder correction capability threshold within the scan time period, since the degradation time difference between the soft error decoder correction capability threshold and the hard error decoder correction capability threshold is the same as the scan time period.

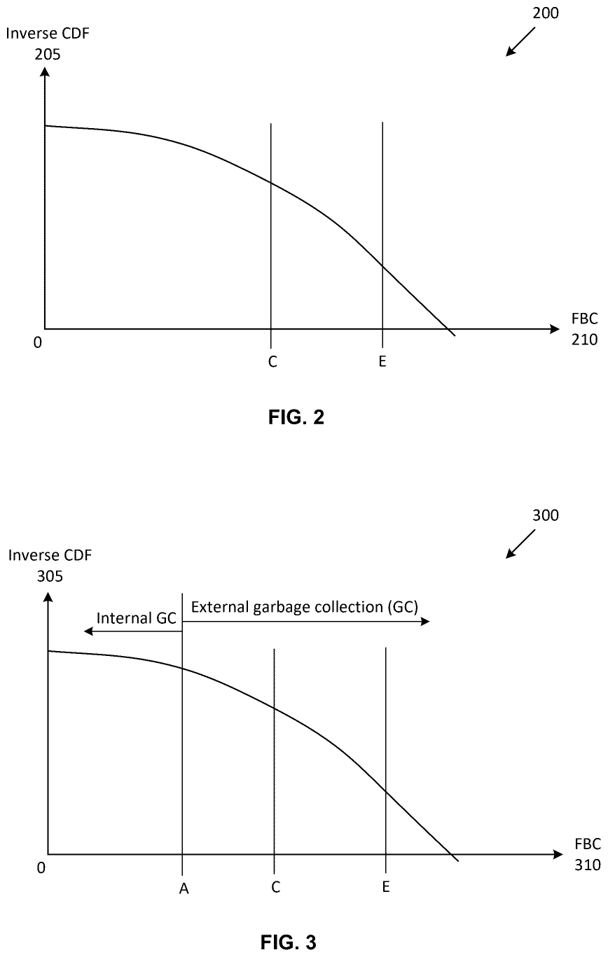

If the FBC from the test read of the memory block is above the FBC threshold, it may indicate that the worst case FBC may exceed the soft error decoder correction capability threshold within the scan time period. In this case, external garbage collection may be performed to reclaim the memory block. For example, the decoder 120 may correct the error in the memory pages causing the FBC, and copy the clean memory pages with the zero FBC to the target memory block. This is further described with reference to FIG. 2.

FIG. 2 illustrates an example graph 200 showing distribution of a FBC 210 against an inverse cumulative distribution function (ICDF) 205 for an external garbage collection process. The FBC 210 is represented by an x-axis of the graph 200, and the ICDF 205 is represented by a y-axis of the graph 200.

As shown in FIG. 2, an FBC threshold C corresponds to a hard error decoder correction capability threshold for a hard decoder, and an FBC threshold E corresponds to a soft error decoder correction capability threshold for a soft decoder. For example, the hard decoder and the soft decoder may be part of the decoder 120. As described with reference to FIG. 1, the media scan module 125 may perform the test reads of the memory device 110 over a scan time period which is set to a time duration for the FBC to degrade from the FBC threshold C to the FBC threshold E. The FBC threshold C may represent a data retention FBC, below which the data is safe or retained in the memory pages, and above which data may have errors. If the FBC from the test read of one or more memory pages of a memory block is above the FBC threshold C, external garbage collection may be performed by the garbage collection module 115 to reclaim the memory block.

FIG. 3 illustrates an example graph 300 showing distribution of a FBC 310 against an ICDF 305 for an internal and an external garbage collection process. The FBC 310 is represented by an x-axis of the graph 300, and the ICDF 305 is represented by a y-axis of the graph 300. As described with reference to FIG. 2, the FBC threshold C corresponds to the hard error decoder correction capability threshold of the hard decoder, and the FBC threshold E corresponds to the soft error decoder correction capability threshold of the soft decoder.

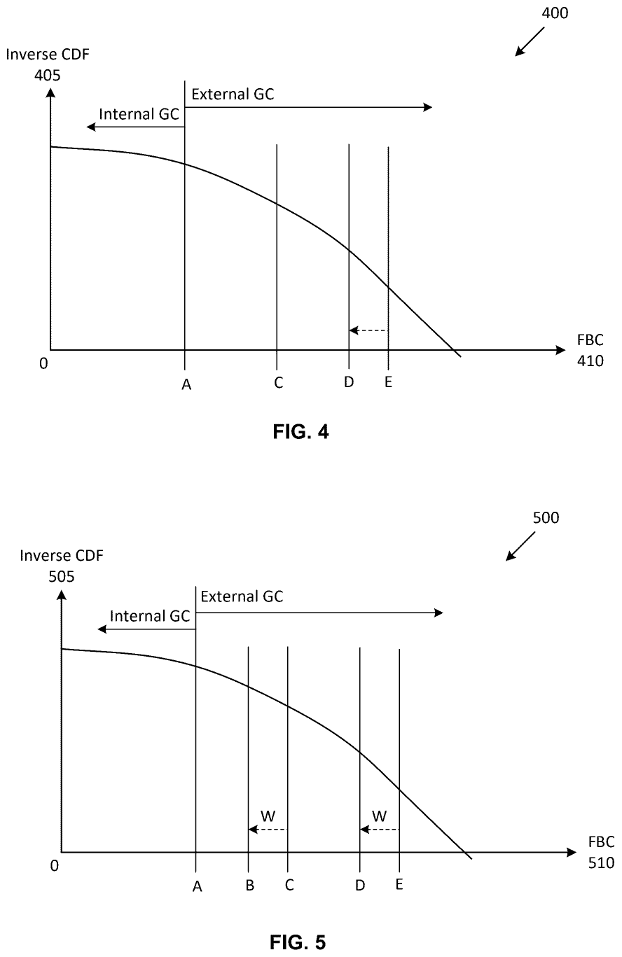

In some embodiments, when the FBC from a test read of a memory block is below an FBC threshold A, an internal garbage collection (GC) operation may be performed. For example, the FBC may be below the FBC threshold A, when a PCS computed by the checksum logic 140 is below a threshold. When the FBC from the test read of the memory block is above the FBC threshold A, an external garbage collection operation may be performed as described with reference to FIG. 2. However, when the internal garbage collection operation is performed, soft errors may become hard errors. A hard error may be defined for a cell having its voltage on the wrong side of an optimal sensing bias and outside of a soft range. For example, the soft range for a TLC NAND may be defined as a range in the order of plus or minus a hundred mv or more around the optimal sensing bias. Hard errors may degrade the correction capability of the soft decoders, e.g., the FBC threshold E representing the soft error decoder correction capability threshold may be reduced. In a rare case, when all errors become hard errors, the soft error decoder correction capability may become the same as the hard error decoder correction capability, e.g., the FBC threshold E may be reduced to the FBC threshold C. This is further described with reference to FIG. 4.

FIG. 4 illustrates an example graph 400 showing distribution of a FBC 410 against an ICDF 405 with a reduction in the scan time period due to degradation of the soft error decoder correction capability resulting from an internal garbage collection operation, in some embodiments of the disclosure. As described with reference to FIG. 2, the FBC threshold C corresponds to the hard error decoder correction capability threshold, and the FBC threshold E corresponds to the soft error decoder correction capability threshold. As described with reference to FIG. 3, the FBC threshold A corresponds to an FBC value below which an in-memory or internal garbage collection operation may be performed, and above which an external garbage collection operation may be performed.

In some cases, hard errors resulting from the in-memory garbage collection operation performed by the memory device 110 may degrade the soft error decoder correction capability. In this case, the soft error decoder correction capability threshold may be degraded to a FBC threshold D from the FBC threshold E, as shown by a back arrow in FIG. 4. In some implementations, degradation of the soft error decoder correction capability may be taken into account by adjusting an interval or a frequency for performing the test reads of the media scan. For example, the memory controller 105 (or firmware executing on the storage device 100) may adjust the interval by adjusting the scan time period to be equal to or shorter than an amount of time for the data retention FBC to increase from the hard decoder correction capability threshold (e.g., FBC threshold C) to the degraded soft decoder correction capability threshold (e.g., FBC threshold D). Thus, the scan time period may be shortened such that the worst case FBC stays below the FBC threshold D. As an example, the scan time period may be reduced from 15 days to 10 days.

In some examples, the test read may be part of a single page read (SPRD) test that is performed after a threshold number of reads on the same memory block. For example, reading a memory page multiple times may cause errors on the memory page or on adjacent memory pages, which is called a read disturb error. The memory scan module 125 may be further operable to adjust the interval by adjusting the threshold number of reads to trigger the SPRD test. The threshold number of reads may be equal to or less than a number of reads for a read disturb FBC to increase from the hard decoder correction capability threshold (e.g., FBC threshold C) to the degraded soft decoder correction capability threshold (e.g., FBC threshold D). Thus, if a memory block has been read a threshold number of times, the media scan module 125 may ensure that there are no read disturb errors in the memory block.

In some embodiments, the memory scan module 125 may be further operable to adjust the interval for performing the test read based on a life cycle stage of the memory device. For example, as the number of program-erase cycles increases with the age of the memory device, the scan time period and the number of SPRD test reads can be reduced to reduce the overhead of performing multiple test reads. As an example, the scan time period can be one month and the SPRD test reads can be 5 million reads at start-of-life (SOL), the scan time period can be 20 days and the SPRD test reads can be 3 million reads at middle-of-life (MOL), and the scan time period can be 15 days and the SPRD test reads can be 2 million reads at end-of-life (EOL) of the memory device 110.

FIG. 5 illustrates an example graph 500 showing distribution of a FBC 510 against an ICDF 505 with a reduction in the FBC threshold due to degradation of the soft error decoder correction capability resulting from an internal garbage collection operation, in some embodiments of the disclosure. As described with reference to FIG. 2, the FBC threshold C corresponds to the hard error decoder correction capability threshold, and the FBC threshold E corresponds to the soft error decoder correction capability threshold. As described with reference to FIG. 3, the FBC threshold A corresponds to an FBC value below which an in-memory or internal garbage collection operation may be performed, and above which an external garbage collection operation may be performed.

In some implementations, the degradation of the soft error decoder correction capability may be taken into account by adjusting the FBC threshold for determining whether to reclaim the target memory block. The adjusted FBC threshold may be equal to or less than a threshold obtained by reducing the hard error decoder correction capability threshold by an amount of the degradation of the soft error decoder correction capability resulting from presence of the hard errors. As shown in FIG. 5, the FBC threshold corresponding to the hard error decoder correction capability threshold may be reduced by an amount W from the threshold C to a threshold B, as shown by a back arrow, which is same as the amount of the degradation of the soft error decoder correction capability from the threshold E to the threshold D resulting from the presence of the hard errors.

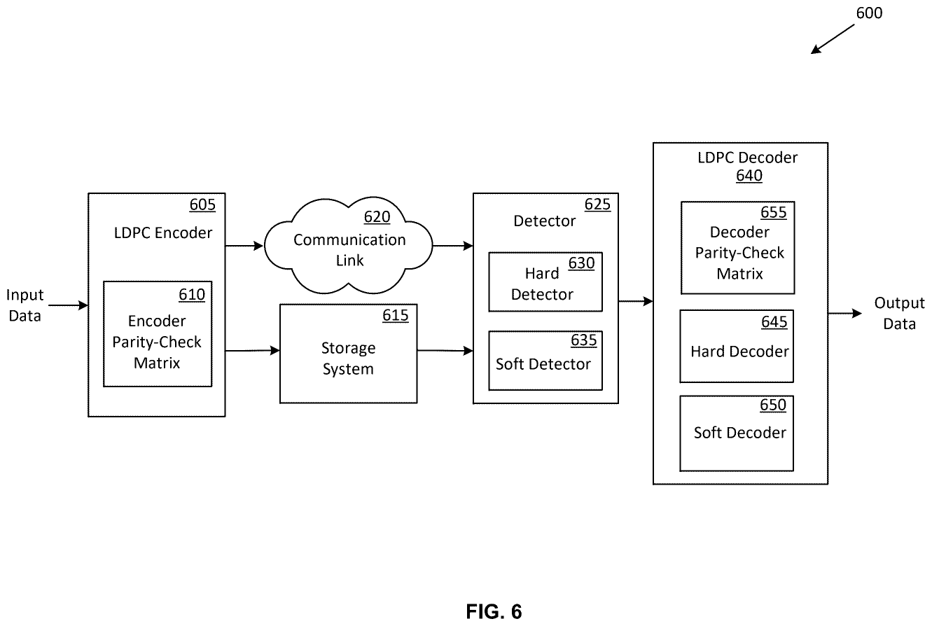

FIG. 6 illustrates a block diagram of an example error correction system 600 that can support boosting reliability of a storage device, in accordance with some embodiments of the disclosure. In various embodiments, certain components of the error correction system 600 may be implemented using a variety of techniques including an application-specific integrated circuit (ASIC), a field-programmable gate array (FPGA), and/or a general-purpose processor (e.g., an Advanced RISC Machine (ARM) core).

The example error correction system 600 includes an LDPC encoder 605 that encodes input data (e.g., by adding parity bits) suitable for storing in a storage system 615 or for transmission through a communication link 620. Encoding the input data enables the use of error correction procedures for correcting bit errors that may occur during operations such as, for example, writing the data into the storage system 615, reading the stored data from the storage system 615, or propagation via the communication link 620. In an example scenario, the communication link 620 can be a wired or wireless communication channel. As an example, the storage system 615 may include the memory device 110. Storage system 615 can be, or can include, for example, a solid-state drive (SSD), a storage card, a Universal Standard Bus (USB) drive, and/other storage components that are implemented using flash memories (e.g., NAND flash memories). It should be understood that various aspects of the disclosure that are described herein with respect to NAND flash memories are equally applicable to various other types of memories and to various types of communication links as well.

In an example implementation, the data and parity bits produced by the LDPC encoder 605 can be stored in memory cells in a multi-level flash memory of the storage system 615. An array of multi-level flash memories can be configured to include multiple memory blocks. Each memory block may include multiple pages. For example, a set of memory cells having a word line that is coupled in common to each of the memory cells can be configured as a page that can be read and written (or programmed) concurrently.

More specifically, a multi-level flash memory can be a type of NAND flash memory containing an array of cells each of which can be used to store multiple bits of data. For example, a tri-level cell (TLC) flash memory can store three bits of data per cell. Each of the three bits of data can be either in a programmed state (logic 0) or in an erased stated (logic 1), thereby allowing for storage of any of eight possible logic bit combinations in each cell. Each cell can be configured to store three bits of data by placing one of eight charge levels in a charge trap layer of a cell. Thus, for example, a cell may be configured to store a 000 logic bit combination by placing a first amount of charge in the cell, a cell may be configured to store a 110 logic bit combination by placing a second amount of charge in the cell, and so on. More generally, a N-bit multi-level cell can have 2^{N} logic states or charge levels representing the different possible combinations of N bits.

Data bit errors may be introduced during storage of the data bits in the multi-level flash memory and/or when writing/reading the data bits in/out of the multi-level flash memory. The data bit errors may be introduced because of various factors such as, for example, hardware defects in the flash memory, aging of the flash memory, interference by adjacent pages, software bugs, and/or read/write timing issues, read/write thresholds, etc.

In some applications, the data bits encoded by the LDPC encoder 605 may be communicated on a communication link 620. Data bit errors may be introduced during propagation of the data bits through the communication link 620. The errors may be introduced because of various factors such as, for example, a transmission line having a sub-optimal characteristic impedance or a noisy wireless communication link (atmospheric disturbances, signal propagation delays, signal fading issues, multi-path issues, inter-symbol interference, etc.).

The detector 625 is configured to read the data bits stored in the storage system 615 and/or to detect the data bits received via the communication link 620. In an example implementation, the detector 625 includes a hard detector 630 and a soft detector 635. The hard detector 630 carries out detection based on voltage thresholds that provide an indication whether a detected bit is either a one or a zero. The input data bits provided to the detector 625 from the storage system 615 and/or the communication link 620 can have deficiencies such as, for example, bit errors and/or signals that vary in amplitude over time (jitter, fading, reflections, etc.). Consequently, the output produced by the hard detector 630 can contain hard errors where one or more bits have been detected inaccurately (a logic 1 read as a logic 0, or vice-versa). The soft detector 635 operates upon the input data and produces an output that is based on statistical probabilities and provides a quantitative indication of a likelihood that a detected bit is either a logic 1 or a logic 0. The statistical probabilities can be characterized by log likelihood ratio (LLR) values. A LLR that is less than 0 indicates that the bit is likely a “1”; and a LLR that is greater than 0 indicates the bit is likely a “0.” The larger the magnitude of the LLR, the more likely that the bit is the designated bit value.

The output of the detector 625 is coupled into the LDPC decoder 640. In an example implementation, the LDPC decoder 640 uses a decoder parity-check matrix 655 during decoding of the data bits. The decoder parity-check matrix 655 corresponds to the encoder parity-check matrix 610, and vice-versa. In the illustrated example, the hard detector bits provided by the detector 625 may be decoded by a hard decoder 645. The soft detector bits and the statistical probability information provided by the detector 625 may be decoded by the soft decoder 650 by use of LLR values. The LDPC decoder 640 can be an example of the decoder 120. In some implementations, the decoder 120 may include the detector 625 and the LDPC decoder 640.

Hard errors can adversely affect the overall performance of the error correction system 600. It is desirable to detect and correct these hard error bits. Data errors may be quantified in various ways such as, for example, in the form of a bit error rate (BER). The overall performance of the error correction system 600 can be characterized by metrics such as, for example, a maximum bit error rate (MBER), a maximum acceptable bit error rate, and/or a residual bit error rate (RBER).

The maximum acceptable BER may be used, for example, to calculate an acceptable signal-to-noise ratio (SNR) of the error correction system 600. The residual bit error rate (RBER) provides an indication of a likelihood that a particular bit is erroneous, and the error is undetected. In general, the performance of the LDPC decoder 640 not only depends upon the RBER but also upon the number of hard errors. The number of hard errors, which may be characterized in the form of a hard error percentage, degrades the error correcting capabilities of the LDPC decoder 640. More particularly, the performance of the soft decoder 650 is dependent in large part upon the LLR values that are used to decode the signals provided to the LDPC decoder 640 by the detector 625. The LLR values may change due to the hard error caused by the in-memory garbage collection operation, which may degrade the soft error decoder correction capability of the soft decoder 650, as described with reference to FIGS. 4 and 5.

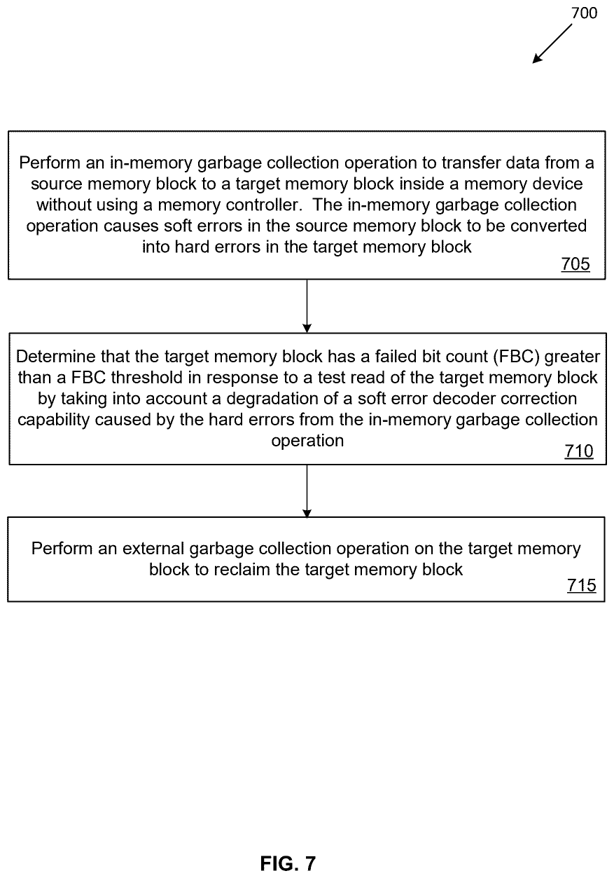

FIG. 7 illustrates a simplified flow chart 700 of an example process to boost reliability of a storage device in accordance with the disclosure. For example, the process may be executed to boost reliability of the storage device 100 or storage system 615.

The process can include, at step 705, performing an in-memory garbage collection operation to transfer data from a source memory block to a target memory block inside a memory device without using a memory controller. The in-memory garbage collection operation may cause soft errors in the source memory block to be converted into hard errors in the target memory block. For example, when a PCS computed by the memory device 110 is below a threshold, the memory device 110 may use the internal garbage collection logic 130 to perform the in-memory garbage collection operation to transfer data from the source memory block 150-1 to the target memory block 150-2 without using the memory controller 105. The in-memory garbage collection operation may cause soft errors in the memory block 150-1 which may get converted into hard errors in the target memory block 150-2.

At step 710, determine that the target memory block has a failed bit count (FBC) greater than a FBC threshold in response to a test read of the target memory block by taking into account a degradation of a soft error decoder correction capability caused by the hard errors from the in-memory garbage collection operation. The test read may be part of a media scan of the memory device performed over a scan time period. For example, the media scan module 125 may perform a media scan process to test read each of the N memory blocks 150-1, 150-2, . . . , 150-n over the scan time period, and determine that the target memory block 150-2 has an FBC that is greater than the FBC threshold.

In one implementation, the FBC threshold may be the threshold C corresponding to the hard error decoder correction capability threshold of the hard decoder 645, and degradation of the soft error decoder correction capability may be taken into account by adjusting an interval for performing the test read by adjusting the scan time period. As described with reference to FIG. 4, the adjusted scan time period is equal to or shorter than an amount of time for the FBC to increase from the threshold C to the threshold D resulting from the presence of the hard errors.

In another implementation, degradation of the soft error decoder correction capability is taken into account by adjusting the FBC threshold for determining to reclaim the target memory block 150-2. For example, the scan time period is not adjusted, but the FBC threshold may be reduced from the threshold C to the threshold B by the same amount (e.g., W) as the difference between the threshold E and the threshold D, as described with reference to FIG. 5.

At step 715, perform an external garbage collection operation on the target memory block to reclaim the target memory block. The garbage collection module 115 may perform the external garbage collection operation on the target memory block 150-2 to reclaim the target memory block 150-2. For example, the garbage collection module 115 may correct the errors in memory pages of the target memory block 150-2 and copy the corrected memory pages back to the target memory block 150-2.

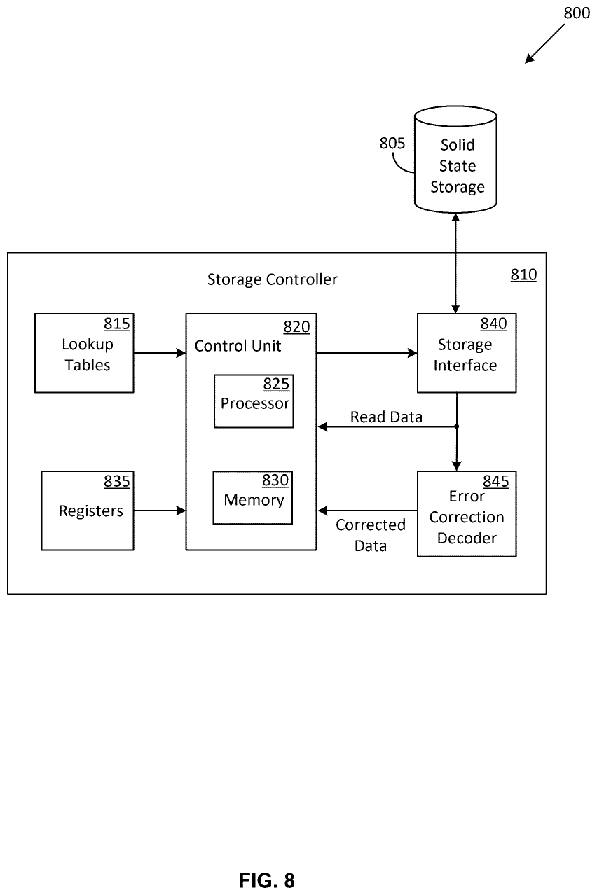

FIG. 8 shows a simplified block diagram illustrating a solid-state storage device 800, which can be an example of an electronic device utilizing the reliability boosting techniques described herein. As shown, solid-state storage device 800 can include a solid-state storage 805 (e.g., implemented using NAND flash memory) and a storage controller 810. Storage controller 810, also referred to as a memory controller, is one example of a device that can perform the processes and techniques described herein. For example, the storage controller 810 can be an example of the memory controller 105. In some embodiments, storage controller 810 can be implemented using integrated circuit components such as an application-specific integrated circuit (ASIC), field programmable gate array (FPGA), etc. Some of the functions can also be implemented in firmware or software. Solid-state storage device 800 can be an example of a solid-state drive (SSD).

Control unit 820 can include one or more processors 825 and a memory 830 (non-transitory computer readable medium) for performing various control functions described herein. Memory 830 can store, for example, firmware and/or software code that are executable by storage controller 810. Storage controller 810 can also include lookup tables 815, which can include, for example, various FBC thresholds, read retry entries of read voltages, and/or other parameters/functions associated with operating solid-state storage 805. Registers 835 can be used to store data for control functions and configurations for storage controller 810.

Control unit 820 can be coupled to solid-state storage 805 through a storage interface 840 (may also be referred to as a memory interface). Error-correction decoder 845 (e.g., LDPC decoder) can perform error-correction decoding on the read data and send the corrected data to controller 820. In some implementations, error correction decoder 845 can be implemented as part of control unit 820. Control unit 820 may also communicate with a host device (e.g., host computer) via a host interface (not shown).

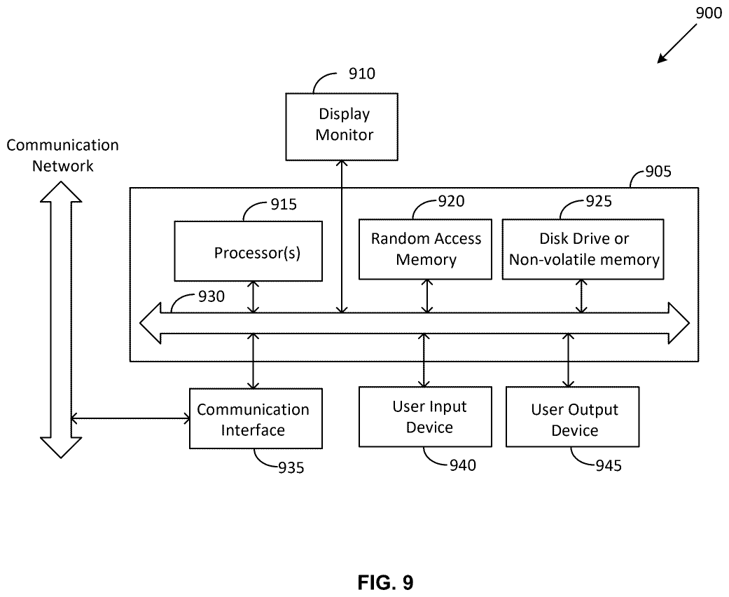

FIG. 9 illustrates a computer system 900 usable for implementing one or more embodiments of the present disclosure. FIG. 9 is merely an example and does not limit the scope of the disclosure as recited in the claims. As shown in FIG. 9, the computer system 900 may include a display monitor 910, a computer 905, a user output device 945, a user input device 940, a communications interface 935, and may further include other computer hardware or accessories.

The computer 905 may include one or more processors such as, for example, the processor 915 that is configured to communicate with a number of peripheral devices via a bus subsystem 930. Some example peripheral devices may include the user output device 945, the user input device 940, and the communications interface 935. The computer 905 may further include a storage subsystem that includes a random-access memory (RAM) 920 and a disk drive 925 or other forms of non-volatile memory.

The user input device 940 can be any of various types of devices and mechanisms for inputting information to the computer 905 such as, for example, a keyboard, a keypad, a touch screen incorporated into the display, and audio input devices (such as voice recognition systems, microphones, and other types of audio input devices). In various embodiments, the user input device 940 is typically embodied as a computer mouse, a trackball, a track pad, a joystick, a wireless remote, a drawing tablet, a voice command system, an eye tracking system, and the like. The user input device 940 typically allows a user to select objects, icons, text and the like that appear on the monitor 910 via a command such as a click of a button or the like.

The user output device 945 can be any of various types of devices and mechanisms for outputting information from the computer 905 such as, for example, a display (e.g., the display monitor 910), non-visual displays such as audio output devices, etc.

The communications interface 935 provides an interface to a communication network. The communications interface 935 may serve as an interface for receiving data from and transmitting data to other systems. Embodiments of the communications interface 935 typically include an Ethernet card, a modem (telephone, satellite, cable, ISDN), (asynchronous) digital subscriber line (DSL) unit, FireWire interface, USB interface, and the like. In an example implementation, the communications interface 935 may be coupled to a computer network, to a FireWire bus, or the like. In other example implementations, the communications interfaces 935 may be physically integrated on the motherboard of the computer 905, and may include a software program, such as soft DSL, or the like.

In various embodiments, the computer system 900 may also include software that enables communications over a network such as the HTTP, TCP/IP, RTP/RTSP protocols, and the like. In alternative embodiments of the present disclosure, other communications software and transfer protocols may also be used, for example IPX, UDP or the like.

The RAM 920 and the disk drive 925 are examples of non-transitory computer-readable media configured to store computer-executable instructions for performing operations associated with various embodiments of the present disclosure, including executable computer code, human readable code, or the like. Other types of computer-readable storage media include floppy disks, removable hard disks, optical storage media such as CD-ROMS, DVDs and bar codes, semiconductor memories such as flash memories, non-transitory read-only-memories (ROMS), battery-backed volatile memories, networked storage devices, and the like. The RAM 920 and the disk drive 925 may be configured to store the basic programming and data constructs that provide the functionality of the present disclosure.

Software code modules and instructions that provide the functionality of the present disclosure may be stored in the RAM 920 and the disk drive 925. These software modules may be executed by the processor 915. The RAM 920 and the disk drive 925 may also provide a repository for storing data used in accordance with the present disclosure.

The RAM 920 and the disk drive 925 may include a number of memories such as a main random-access memory (RAM) for storage of instructions and data during program execution and a read-only memory (ROM) in which fixed non-transitory instructions are stored. The RAM 920 and the disk drive 925 may include a file storage subsystem providing persistent (non-volatile) storage for program and data files. The RAM 920 and the disk drive 925 may also include removable storage systems, such as removable flash memory.

The bus subsystem 930 provides a mechanism for letting the various components and subsystems of the computer 905 communicate with each other as intended. Although the bus subsystem 930 is shown schematically as a single bus, alternative embodiments of the bus subsystem may utilize multiple busses.

It will be readily apparent to one of ordinary skill in the art that many other hardware and software configurations are suitable for use with the present disclosure. For example, the computer 905 may be a desktop, portable, rack-mounted, or tablet configuration. Additionally, the computer 905 may be a series of networked computers. In still other embodiments, the techniques described above may be implemented upon a chip or an auxiliary processing board.

Various embodiments of the present disclosure can be implemented in the form of logic in software or hardware or a combination of both. The logic may be stored in a computer-readable or machine-readable non-transitory storage medium as a set of instructions adapted to direct a processor of a computer system to perform a set of steps disclosed in embodiments of the present disclosure. The logic may form part of a computer program product adapted to direct an information-processing device to perform a set of steps disclosed in embodiments of the present disclosure. Based on the disclosure and teachings provided herein, a person of ordinary skill in the art will appreciate other ways and/or methods to implement the present disclosure.

The data structures and code described herein may be partially or fully stored on a computer-readable storage medium and/or a hardware module and/or hardware apparatus. A computer-readable storage medium includes, but is not limited to, volatile memory, non-volatile memory, and magnetic and optical storage devices, such as disk drives, magnetic tape, CDs, DVDs, or other media, now known or later developed, that are capable of storing code and/or data. Hardware modules or apparatuses described herein include, but are not limited to, ASICs, FPGAs, dedicated or shared processors, and/or other hardware modules or apparatuses now known or later developed.

The methods and processes described herein may be partially or fully embodied as code and/or data stored in a computer-readable storage medium or device, so that when a computer system reads and executes the code and/or data, the computer system performs the associated methods and processes. The methods and processes may also be partially or fully embodied in hardware modules or apparatuses, so that when the hardware modules or apparatuses are activated, they perform the associated methods and processes. The methods and processes disclosed herein may be embodied using a combination of code, data, and hardware modules or apparatuses.

The embodiments disclosed herein are not to be limited in scope by the specific embodiments described herein. Various modifications of the embodiments of the present disclosure, in addition to those described herein, will be apparent to those of ordinary skill in the art from the foregoing description and accompanying drawings. Further, although some of the embodiments of the present disclosure have been described in the context of a particular implementation in a particular environment for a particular purpose, those of ordinary skill in the art will recognize that the disclosure's usefulness is not limited thereto and that the embodiments of the present disclosure can be beneficially implemented in any number of environments for any number of purposes.

What is claimed is:

1. A method to boost reliability of a storage device, comprising:
performing an in-memory garbage collection operation to transfer data from a source memory block to a target memory block inside a memory device without using a memory controller, wherein the in-memory garbage collection operation causes soft errors in the source memory block to be converted into hard errors in the target memory block;
determining that the target memory block has a failed bit count (FBC) greater than a FBC threshold in response to a test read of the target memory block by taking into account a degradation of a soft error decoder correction capability caused by the hard errors from the in-memory garbage collection operation; and
performing an external garbage collection operation on the target memory block to reclaim the target memory block.

2. The method of claim 1, wherein the degradation of the soft error decoder correction capability is taken into account by adjusting an interval for performing the test read, and wherein the FBC threshold is a hard error decoder correction capability threshold.

3. The method of claim 2, wherein the test read is part of a media scan of the memory device performed over a scan time period, and adjusting the interval includes adjusting the scan time period.

4. The method of claim 3, wherein the adjusted scan time period is equal to or shorter than an amount of time for a data retention FBC to increase from the hard error decoder correction capability threshold to a degraded soft error decoder correction capability threshold resulting from presence of the hard errors.

5. The method of claim 2, wherein the test read is part of a single page read (SPRD) test that is performed after a threshold number of reads on the target memory block, and adjusting the interval includes adjusting the threshold number of reads to trigger the SPRD test.

6. The method of claim 5, wherein the threshold number of reads is equal to or less than a number of reads for a read disturb FBC to increase from the hard error decoder correction capability threshold to a degraded soft decoder correction capability threshold resulting from presence of the hard errors.

7. The method of claim 2, wherein the interval for performing the test read is further adjusted based on a life cycle stage of the memory device.

8. The method of claim 1, wherein the degradation of the soft error decoder correction capability is taken into account by adjusting the FBC threshold for determining to reclaim the target memory block.

9. The method of claim 8, wherein the adjusted FBC threshold is equal to or less than a threshold obtained by reducing the hard error decoder correction capability threshold by an amount of the degradation of the soft error decoder correction capability resulting from presence of the hard errors.

10. The method of claim 1, wherein the in-memory garbage collection is performed by the memory device when a partial checksum (PCS) computed by the memory device is below a threshold.

11. A storage device comprising:
a memory controller having a soft error decoder and a hard error decoder; and
a memory device having an internal garbage collection logic operable to perform an in-memory garbage collection operation to transfer data from a source memory block to a target memory block inside the memory device,
wherein the in-memory garbage collection operation causes soft errors in the source memory block to be converted into hard errors in the target memory block, and
wherein the memory controller is operable to determine that the target memory block has a failed bit count (FBC) greater than a FBC threshold in response to a test read of the target memory block by taking into account a degradation of a soft error decoder correction capability of the soft error decoder caused by the hard errors from the in-memory garbage collection operation, and perform an external garbage collection operation on the target memory block to reclaim the target memory block.

12. The storage device of claim 11, wherein the memory controller is further operable to take the degradation of the soft error decoder correction capability into account by adjusting an interval for performing the test read, and wherein the FBC threshold is a hard error decoder correction capability threshold of the hard error decoder.

13. The storage device of claim 12, wherein the test read is part of a media scan of the memory device performed over a scan time period, and adjusting the interval includes adjusting the scan time period.

14. The storage device of claim 13, wherein the adjusted scan time period is equal to or shorter than an amount of time for a data retention FBC to increase from the hard error decoder correction capability threshold to a degraded soft error decoder correction capability threshold resulting from presence of the hard errors.

15. The storage device of claim 12, wherein the test read is part of a single page read (SPRD) test that is performed after a threshold number of reads on the target memory block, and wherein adjusting the interval includes adjusting the threshold number of reads to trigger the SPRD test.

16. The storage device of claim 15, wherein the threshold number of reads is equal to or less than a number of reads for a read disturb FBC to increase from the hard error decoder correction capability threshold to a degraded soft decoder correction capability threshold resulting from presence of the hard errors.

17. The storage device of claim 12, wherein the memory controller is further operable to adjust the interval for performing the test read based on a life cycle stage of the memory device.

18. The storage device of claim 11, wherein the memory controller is further operable to take the degradation of the soft error decoder correction capability into account by adjusting the FBC threshold for determining to reclaim the target memory block.

19. The storage device of claim 18, wherein the adjusted FBC threshold is equal to or less than a threshold obtained by reducing the hard error decoder correction capability threshold by an amount of the degradation of the soft error decoder correction capability resulting from presence of the hard errors.

20. The storage device of claim 11, wherein the memory device is further operable to perform the in-memory garbage collection when a partial checksum (PCS) computed by the memory device is below a threshold.
